(19) United States
(12) Patent Application Publication
(10) Pub. No.: US 2020/0043867 A1
(43) Pub. Date: Feb. 6, 2020

(54) SUBSTRATE AND METHOD FOR PREPARING THE SAME

(71) Applicant: ENKRIS SEMICONDUCTOR, INC., Suzhou (CN)

(72) Inventors: Liyang ZHANG, Suzhou (CN); Kai CHENG, Suzhou (CN)

(21) Appl. No.: 16/653,038

(22) Filed: Oct. 15, 2019

Related U.S. Application Data
(63) Continuation of application No. PCT/CN2017/100946, filed on Sep. 7, 2017.

(51) Int. Cl. H01L 23/00; H01L 29/06; H01L 29/267; H01L 21/02

(52) U.S. Cl. CPC H01L 23/562; H01L 21/02381; H01L 29/267; H01L 29/0603

(57) ABSTRACT

A substrate and a method for preparing the same relate to the field of semiconductors. The substrate includes a base substrate (10); a thin film layer (11), wherein the thin film layer (11) covers a part of a surface of the base substrate (10), so that the base substrate (10) is provided with an exposed surface (100) that is not covered by the thin film layer (11); and recessed hole(s) (101) formed in at least a part of the exposed surface (100). The substrate with the recessed hole(s) may release stresses that are generated due to lattice mismatch and thermal stress mismatch when an epitaxial layer is grown on the substrate and reduce the risk of occurrence of defects and cracks due to excessive pressure, thereby reducing the warping of a semiconductor subsequently prepared on the substrate and making it have a better quality and performance.

### CROSS-REFERENCE TO RELATED APPLICATIONS

This application is a continuation of International Application No. PCT/CN2017/100946, filed on Sep. 7, 2017, the disclosure of which is hereby incorporated by reference in its entirety.

### TECHNICAL FIELD

Embodiments of the present disclosure relate to the field of semiconductor technology, in particular to a substrate and a method for preparing the same.

### BACKGROUND

III-V compound semiconductors such as GaAs, InP, GaN, etc. have advantages such as high electron mobility and wide bandgap with respect to traditional semiconductors such as Ge, Si, etc. and are widely used in the fields of microwave and optoelectronic devices. At present, sapphire, silicon and silicon carbide are commonly used as substrates for growth of the III-V compound semiconductors. However, when the III-V compound semiconductors (such as GaN) are grown on the above-mentioned substrates, there are some problems such as lattice mismatch and thermal stress mismatch, which may lead to warping and even cracking in a grown GaN epitaxial layer, and may also lead to high threading dislocation density in the GaN epitaxial layer, thereby affecting the performance of materials and devices, causing difficulty in subsequent processes of device fabrication, and increasing production costs. The prior art tries to solve the relative problems by performing photolithography to the substrate so as to make patterns on the substrate, or by adding a buffer layer in the middle of the epitaxial layer.

In the process of implementing the present disclosure, the inventors have found that at least the following problems exist in the prior art:

it is relatively difficult to grow a high quality III-V compound semiconductor structure on a substrate at low cost,

1) the substrate is processed by photolithography or etching to make patterned substrates, but this process is complex, the production cost is high, and the epitaxial layer which is subsequently grown may be contaminated;

2) adding a buffer layer, such as multi-layer AlGaN, in the middle of an epitaxial layer may accumulate stress, balance thermal tension stress in the epitaxial layer that is exerted by the substrate, and realize warping control of the epitaxial layer on the substrate. However, such structure still has a high threading dislocation density, makes stress releasing become faster, and limits the thickness of growth of the epitaxial layer.

### SUMMARY

Purposes of the present disclosure are to provide a substrate and a method for preparing the same, which can solve problems that stresses are generated due to lattice mismatch and thermal stress mismatch in the preparation process.

An embodiment of the present disclosure discloses a substrate including a base substrate; a thin film layer, wherein the thin film layer covers a part of a surface of the base substrate, so that the base substrate is provided with an exposed surface that is not covered by the thin film layer; and recessed hole(s) formed in at least a part of the exposed surface.

Preferably, a diameter of the recessed hole(s) is less than 500 nm.

Preferably, the base substrate is made of silicon, silicon carbide or gallium nitride.

Preferably, the thin film layer is made of Al, Fe, Mg or In.

An embodiment of the present disclosure discloses a method for preparing a substrate including the following steps: S1, providing a reaction container in which a base substrate is mounted; S2, conducting a metal source into the reaction container, and forming a thin film layer on a surface of the base substrate, wherein a part of the surface of the base substrate is covered by the thin film layer, so that the base substrate is provided with an exposed surface that is not covered by the thin film layer; and S3, conducting a corrosive gas into the reaction container to form recessed hole(s) in at least a part of the exposed surface.

Preferably, in the step S3, a diameter of the recessed hole(s) is less than 500 nm.

Preferably, in the step S1, the base substrate is made of silicon, silicon carbide or gallium nitride.

Preferably, in the step S1, the reaction container is a metal-organic chemical vapor deposition reactor, an atomic deposition reactor or a chemical beam epitaxial reactor.

Preferably, in the step S3, the corrosive gas is NH₃, H₂, HCl or Cl₂.

Preferably, when the base substrate is made of silicon, after the step S3, a Ga source is conducted into the reaction container, or a Ga-containing compound is prepared on the thin film layer.

The beneficial effects of the present disclosure lie in that, for the substrate disclosed in the present disclosure, since the recessed hole(s) is formed in a part of the surface of the substrate, the stress that are generated due to lattice mismatch and thermal stress mismatch when an epitaxial layer is grown on the substrate in the subsequent semiconductor process can be released, and a risk of occurrence of defects and cracks in the epitaxial layer as grown due to excessive pressure may be reduced, thereby reducing a warping of a semiconductor subsequently prepared on the substrate and making the semiconductor have a better quality and performance. The method for preparing the substrate disclosed in the present disclosure is simple, efficient and low-cost, may allow the recessed hole(s) to be formed in the substrate without complicated etching process, may allow forming the recessed hole in the substrate to be performed in one and the same reaction container successively with a subsequent epitaxial growth process, and may release the stresses generated due to lattice mismatch and thermal stress mismatch when the epitaxial layer is grown on the substrate.

The above description is only an overview of the technical solutions of the present disclosure. In order for the technical means of the present disclosure to be more clearly understood and to be implemented in accordance with the contents of this specification, the preferable embodiments of the present disclosure will be described hereinafter in detail with reference to the accompanying drawings.

### BRIEF DESCRIPTION OF DRAWINGS

The following will describe the present disclosure in association with embodiments and with reference to the drawings. In the drawings:

FIG. 1 is a schematic structural diagram of a semiconductor device adopting a substrate as illustrated in an embodiment of the present disclosure;

FIG. 2 is a TEM characterization diagram of a semiconductor device adopting a substrate as illustrated in an embodiment of the present disclosure.

### DETAILED DESCRIPTION

The drawings are only used for exemplary illustration, and can not be interpreted as limitation to the present patent. The following will further describe the technical solutions of the present disclosure in association with the drawings and embodiments. In the description of embodiments of the present disclosure, it is understood that, when an element is stated to be “above” or “below” another element, the element can be “directly” located “above” or “below” the other element (they directly contacts each other), or the element can be “indirectly” located “above” or “below” the other element (there is a further element between them). For the sake of convenience or clarity, the thickness and dimension of each element as shown in the drawings may be enlarged, shrunk, or schematically depicted, and the dimension of the elements do not represent the real dimension.

The main equipment for carrying out the present disclosure is a metal-organic chemical vapor deposition reactor, an atomic deposition reactor or a chemical beam epitaxial reactor. For preparation of different semiconductor structures, various growth parameters are adjusted according to specific conditions.

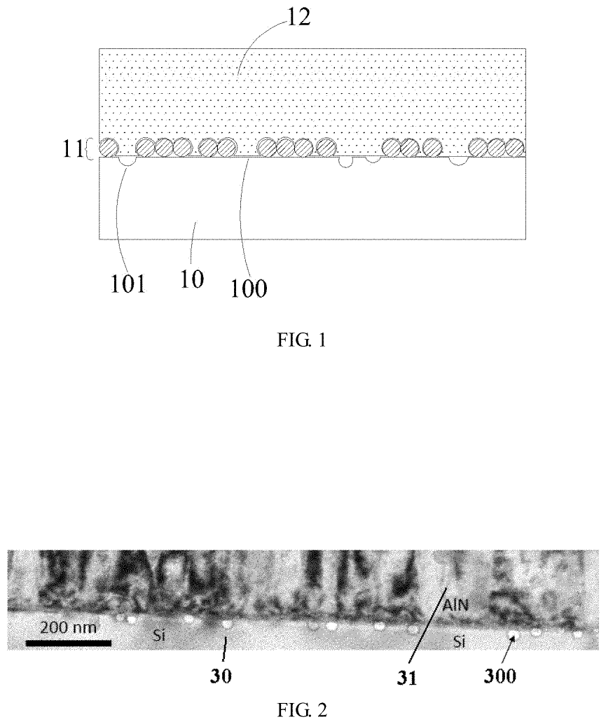

Please refer to FIG. 1 which is a schematic structural diagram of a semiconductor device adopting a substrate according to an embodiment of the present disclosure. The substrate shown in the embodiment of the present disclosure includes a base substrate 10, a thin film layer 11 and recessed hole(s) 101. A part of a surface of the base substrate 10 is covered by the thin film layer 11, i.e., the base substrate 10 has an exposed surface 100 that is not covered by the thin film layer 11. The recessed hole(s) 101 is randomly formed in at least a part of the exposed surface 100. It should be understood that the configuration illustrated in FIG. 1 is not the only configuration of the present disclosure, the exposed surface 101 is randomly distributed on the surface of the base substrate 10, and the size of the exposed surface 100 is variable. The recessed hole(s) 101 is also randomly distributed on the exposed surface 100, the size of the recessed hole(s) 101 is variable, and the diameter of the recessed hole(s) 101 is preferably less than 500 nm.

The base substrate 10 is preferably made of silicon. Of course, the base substrate 10 may also be made of silicon carbide, gallium nitride or the like.

The thin film layer 11 is a metal thin film, and is preferably an aluminum thin film. Of course, in other embodiments, the thin film layer 11 may also be other metal thin films such as a magnesium thin film, an iron thin film, and an indium thin film.

A semiconductor device adopting a substrate according to an embodiment of the present disclosure includes an epitaxial layer 12 disposed on the substrate. Taking a GaN device on a substrate of which a base substrate is made of Si as an example, an epitaxial layer 12 may include AlN, GaN, AlGaN, or the like.

The beneficial effects of this embodiment of the present disclosure lie in that, for the substrate disclosed in the present disclosure, since the recessed holes are randomly formed in a part of the surface of the substrate, the stresses that are generated due to the lattice mismatch and the thermal stress mismatch when the epitaxial layer is grown on the substrate in the subsequent semiconductor processes can be released, and a risk of occurrence of defects and cracks in the epitaxial layer as grown due to excessive pressure may be reduced, thereby reducing the warping degree of the semiconductor subsequently prepared on the substrate and making the semiconductor have a better quality and performance. In addition, what is disclosed in the present disclosure may be a flexible substrate.

In association with FIG. 1, the present disclosure also discloses a method for preparing a substrate, as follows:

S1, providing a reaction container in which a base substrate 10 is mounted;

S2, conducting a metal source into the reaction container, and forming a thin film layer 11 on a surface of the base substrate 10, a part of the surface of the base substrate 10 being covered by the thin film layer 11, so that the base substrate 10 is provided with an exposed surface 100 that is not covered by the thin film layer 11; and

S3, conducting a corrosive gas into the reaction container to form recessed hole(s) 101 in at least a part of the exposed surface. The diameter of the recessed hole(s) 101 is preferably less than 500 nm.

In the step S3 of the embodiment, the reaction container may be heated to the temperature of an epitaxial layer 12 of the semiconductor device subsequently adopting the substrate of the present disclosure (e.g., the growth temperature of a III-V compound AlN at 500-1400° C.), and then corrosive gas may pass into the reaction container, so that the epitaxial layer 12 can be grown in the reaction container right after the recessed hole(s) 101 is formed in the exposed surface of the base substrate 10.

In the above preparation method, the reaction container is preferably an metal-organic chemical vapor deposition reactor. Of course, in other embodiments, the reaction container may also be an atomic deposition reactor or a chemical beam epitaxial reactor, as desired in processes. The substrate 20 is a silicon substrate; of course, in other embodiments the substrate 20 may also be a silicon carbide substrate or a gallium nitride substrate. The metal source is an aluminum source; of course, in other embodiments the metal source may also be another metal source such as a magnesium source, an iron source, and an indium source. The corrosive gas is NH₃; of course, in other embodiments, the corrosive gas may also be HCl or H₂ or Cl₂.

Referring to FIG. 2, FIG. 2 is a TEM characterization diagram of a semiconductor device using a substrate according to an embodiment of the present disclosure. A base substrate 30 is made of silicon, and a part of the surface of the base substrate 30 is covered with a thin film layer (not labeled). A plurality of recessed holes 300 are formed in a part of an exposed surface (not labeled) of the silicon substrate 30 that is not covered by the thin film layer, and then an epitaxial layer 31 (e.g., AlN) is formed thereon. Forming the plurality of recessed holes 300 in a part of the exposed surface of the base substrate 30 may release the stress generated due to the lattice mismatch and the thermal stress mismatch between the base substrate 30 and a GaN epitaxial layer when the GaN epitaxial layer is grown, and therefore, the GaN epitaxial layer as grown is prevented from having high warping and even cracking.

The beneficial effects of this embodiment of the present disclosure lie in that, the method for preparing the substrate is simple, efficient and low-cost, may allow the recessed holes to be formed in the substrate without complicated etching process, may be performed in one and the same reaction container successively with a subsequent epitaxial growth process, and may release the stress generated due to lattice mismatch and thermal stress mismatch when the epitaxial layer is grown on the substrate.

A method for enlarging the diameter of recessed hole(s) 101 is also disclosed in another embodiment of the present disclosure. When a base substrate 10 is made of silicon, after step S3, i.e. conducting a corrosive gas into a reaction container to form the recessed hole(s) 101 in at least a part of an exposed surface, a Ga source is conducted into the reaction container, or a Ga-containing compound (e.g., GaN, AlGaN, AlINGaN, etc.) is epitaxially grown on a thin film layer 11, and the recessed hole(s) 101 is further etched by means of a remelting reaction between Ga atoms and the silicon substrate, thereby enlarging the diameter of the recessed hole(s) 101.

The beneficial effects of this embodiment of the present disclosure lie in that the diameter of the recessed hole(s) 101 may be enlarged through the remelting reaction between Ga and silicon.

The technical features of the above-mentioned embodiments may be combined arbitrarily. For the sake of concise description, not all possible combinations of the technical features in the above-mentioned embodiments are described. Of course, as long as there is no contradiction in the combinations of these technical features, they should be considered as falling in the scope of the specification.

The above-mentioned embodiments are merely illustrative of several implementations of the present disclosure, and the description thereof is relatively specific and detailed, but they cannot be understood as limiting the scope of the present disclosure. It should be noted that a number of variations and modifications may be made by those skilled in the art without departing from the spirit and scope of the present disclosure.

What is claimed is:

1. A substrate, comprising:
a base substrate;
a thin film layer, wherein the thin film layer covers a part of a surface of the base substrate, so that the base substrate is provided with an exposed surface that is not covered by the thin film layer; and
recessed hole(s) formed in at least a part of the exposed surface.

2. The substrate of claim 1, wherein a diameter of the recessed hole is less than 500 nm.

3. The substrate of claim 1, wherein the base substrate is made of one of silicon, silicon carbide and gallium nitride.

4. The substrate of claim 1, wherein the thin film layer is made of one of Al, Fe, Mg and In.

5. A method for preparing a substrate, comprising the following steps:
S1, providing a reaction container in which a base substrate is mounted;
S2, conducting a metal source into the reaction container, and forming a thin film layer on a surface of the base substrate, wherein a part of a surface of the base substrate is covered by the thin film layer, so that the base substrate is provided with an exposed surface that is not covered by the thin film layer; and
S3, conducting a corrosive gas into the reaction container to form recessed hole(s) in at least a part of the exposed surface.

6. The method of claim 5, wherein a diameter of the recessed hole in the step S3 is less than 500 nm.

7. The method of claim 5, wherein in the step S1, the base substrate is made of one of silicon, silicon carbide and gallium nitride.

8. The method of claim 5, wherein in the step S1, the reaction container is a metal-organic chemical vapor deposition reactor, an atomic deposition reactor or a chemical beam epitaxial reactor.

9. The method of claim 5, wherein in the step S3, the corrosive gas is one of NH₃, H_{z}, HCl and Cl₂.

10. The method of claim 7, wherein when the base substrate is made of silicon, after the step S3, a Ga source is conducted into the reaction container, or a Ga-containing compound is prepared on the thin film layer.
